(19) United States
(12) Patent Application Publication
(10) Pub. No.: US 2025/0067810 A1
(43) Pub. Date: Feb. 27, 2025

(54) INFORMATION PROCESSING DEVICE

(71) Applicant: TOYOTA JIDOSHA KABUSHIKI KAISHA, Toyota-shi (JP)

(72) Inventors: Keisuke ISOMURA, Kariya-shi (JP); Tatsuhiko Sasaki, Toyota-shi (JP); Masahiro Kagami, Nagoya-shi (JP); Hirobumi Isogai, Toyota-shi (JP)

(73) Assignee: TOYOTA JIDOSHA KABUSHIKI KAISHA, Toyota-shi (JP)

(21) Appl. No.: 18/768,432

(22) Filed: Jul. 10, 2024

(30) Foreign Application Priority Data
Aug. 22, 2023 (JP) 2023-134544

(51) Int. Cl. G01R 31/392; B60L 53/65; B60L 53/68; B60L 53/80; G01R 31/367

(52) U.S. Cl. CPC G01R 31/392; B60L 53/65; B60L 53/68; B60L 53/80; G01R 31/367

(57) ABSTRACT

A control unit configured to execute: acquiring first information regarding deterioration of a battery at the start of reuse of a battery to be reused by a business operator; acquiring second information regarding a usage environment of the battery by the business operator; acquiring third information regarding performance of the battery required by the business operator; and outputting a recovery time of the battery after the business operator uses the battery according to the first information, the second information, and the third information.

### CROSS-REFERENCE TO RELATED APPLICATION

This application claims priority to Japanese Patent Application No. 2023-134544 filed on Aug. 22, 2023, incorporated herein by reference in its entirety.

### BACKGROUND

### 1. Technical Field

The disclosure relates to an information processing device.

### 2. Description of Related Art

Japanese Unexamined Patent Application Publication No. 2011-146389 (JP 2011-146389 A) discloses acquiring electrical characteristic information and use history information from a secondary battery module, performing storage thereof in a database, and performing grading for reuse based on the information. Also, Japanese Unexamined Patent Application Publication No. 2007-141464 (JP 2007-141464 A) discloses a chargeable/dischargeable secondary battery module that is operated being controlled by a battery controller, and that stores at least one of its own electrical characteristic information or use history information.

### SUMMARY

An object of the disclosure is to predict a recycling time of a battery with higher precision.

An information processing device according to an aspect of the disclosure includes a control unit configured to execute
acquiring, with respect to a battery that is to be reused by a business operator, first information relating to deterioration of the battery when starting reuse of the battery, acquiring second information regarding a usage environment of the battery by the business operator, acquiring third information regarding performance of the battery that is required by the business operator, and
outputting a recovery time of the battery after the business operator uses the battery, in accordance with the first information, the second information, and the third information.

Other aspects of the disclosure relate to an information processing method that causes a computer to execute the above information processing, a program that causes the computer to execute the information processing method, and a computer-readable storage medium that non-transitorily stores the program.

According to the disclosure, the recycling time of the battery can be predicted with higher precision.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating a schematic configuration of a system according to an embodiment;

FIG. 2 is a diagram illustrating a change in SOH of a battery;

FIG. 3 is a block diagram schematically illustrating an example of a configuration of each of a vehicle, a business operator terminal, and a server constituting the system;

FIG. 4 is a diagram illustrating a table configuration of a battery information DB and a business operator information DB; and

FIG. 5 is a flowchart illustrating a process of outputting a battery recovery time in the server.

### DETAILED DESCRIPTION OF EMBODIMENTS

It is conceivable that information regarding the usage status of the battery is transmitted from the vehicle equipped with the battery. However, when the battery is detached from the vehicle at the time of reuse of the battery, the information on the usage state of the battery cannot be transmitted thereafter, and thus the usage state of the battery becomes unknown. Also, it is not known where the battery will be used afterwards. As a result, it becomes difficult to predict the location and timing of generation of the recycled material.

In order to solve such a problem, an information processing device that is one of aspects of the present disclosure includes a control unit configured to execute: acquiring first information regarding deterioration of the battery at the start of reuse of the battery to be reused by a business operator; acquiring second information regarding a usage environment of the battery by the business operator; acquiring third information regarding performance of the battery required by the business operator; and outputting a recovery time of the battery after the business operator uses the battery in accordance with the first information, the second information, and the third information.

A business operator is a business operator using a battery. This battery is a battery that has previously been used elsewhere and is reused. The battery is, for example, a battery mounted on a Battery Electric Vehicle (BEV). At the start of the use of the battery by the business operator, the battery is deteriorated to some extent. The first information is information related to deterioration of the battery at the time when the business operator starts using the battery. The first information may be, for example, information about State of Health (SOH of the battery). SOH is the ratio of the current full charge capacity (Ah) to the initial full charge capacity (Ah).

Here, in a case where the battery is removed from the vehicle, for example, before the use of the battery is started in the business operator, there is a possibility that the usage status up to that time is not known. On the other hand, a battery mounted on a vehicle, for example, periodically transmits a state of the battery from the vehicle. Therefore, the control unit grasps the state of the battery before the battery is removed from the vehicle. The state of the battery immediately before the battery is removed from the vehicle and the state of the battery at the start of the use of the battery by the reuse destination business operator can be considered to be substantially equal. Therefore, the control unit can acquire the first information based on the information about the battery transmitted from the vehicle. As another example, a business operator that removes the battery from the vehicle or a business operator that mediates the battery may measure SOH of the battery, for example. Then, the control unit may acquire SOH as the first information.

Further, the second information is information on the usage environment of the battery by the business operator of the reuse destination, and is information on the deterioration of the battery caused by the use of the battery by the business operator of the reuse destination. The use of batteries by business operators that are reused deteriorates the batteries. The degree of deterioration is affected by the usage environment of the battery. Therefore, the second information is also information about the degree of deterioration of the battery. The second information may include, for example, at least one of information about the type of renewable energy that charges the battery and information about the amount of electric power input to the battery. In power generation using renewable energy, it is conceivable to charge the battery. For example, in power generation using renewable energy such as photovoltaic power generation, wind power generation, and geothermal power generation, since the amount of power generation may be influenced by weather, it is conceivable that excess electric power is stored in a battery and is discharged from the battery when electric power is insufficient. This storage and discharging correlates with the deterioration of the battery. Since the mode of power storage and discharging differs depending on the type of renewable energy, the degree of deterioration of the battery also varies depending on the type of renewable energy. The amount of electric power input to the battery also correlates with deterioration of the battery. Therefore, the degree of deterioration of the battery also varies depending on the amount of electric power input to the battery. The type of renewable energy or the amount of electric power input to the battery is registered by, for example, a business operator.

In addition, the third information is information related to the performance of the battery required by the business operator of the reuse destination. The required performance of the battery varies depending on the usage of the battery. The third information may be determined by a business operator to which the battery is reused, or may be estimated according to, for example, an industry. The third information is the performance required for the reuse destination business operator to use the battery, and when the actual performance of the battery falls below the performance of the required battery, it is necessary to replace the battery. The third information may include, for example, at least one of information on a lower limit value of a capacity of the battery and information on an output of the battery. As the battery deteriorates, the capacity of the battery decreases. As a result, the amount of electric power that can be charged to the battery decreases, and therefore, when the amount of electric power that can be charged falls below the lower limit of the capacity of the battery required by the business operator, the battery needs to be replaced. In addition, the output of the battery decreases as the battery deteriorates. As a result, it may be difficult for the business operator to obtain the required output. In this case too, the battery needs to be replaced. Such performance of the battery required by the business operator is registered by the business operator, for example.

As described above, the performance of the battery at the start of use is known on the basis of the first information, and the degree of deterioration of the battery is known on the basis of the second information. Therefore, based on these pieces of information, the control unit can predict how the performance of the battery changes in the business operator of the reuse destination. When the performance of the battery falls below the performance indicated by the third information, it is considered that the reused business operator replaces the battery. That is, it is possible to predict a time when the battery can be recovered from the business operator of the reuse destination. By the control unit outputting this time, it is possible to predict the time when the battery is collected from the business operator after the end of use of the battery before the business operator starts using the battery. Therefore, it is possible to predict a time when the battery can be recycled. Further, by registering the location of the business operator in advance, the control unit can also predict a position where the battery can be recovered.

Hereinafter, embodiments of the present disclosure will be described with reference to the drawings. The configurations of the following embodiments are illustrative, and the present disclosure is not limited to the configurations of the embodiments. Further, the following embodiments can be combined as much as possible.

### First Embodiment

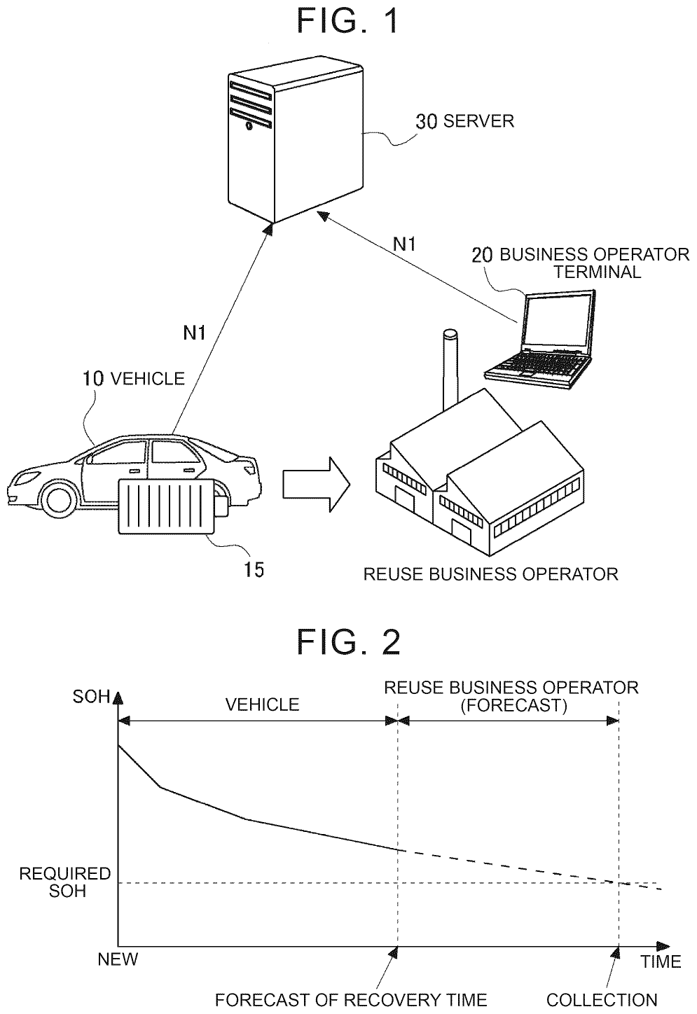

FIG. 1 is a schematic diagram of a system 1 according to an embodiment. In the example of FIG. 1, the system 1 includes a vehicle 10 equipped with a battery 15, a business operator terminal 20 used by a reuse business operator, and a server 30. There may be a plurality of vehicles 10 and a plurality of business operator terminals 20. The vehicle 10, the business operator terminal 20, and the server 30 are connected to each other by a network N1. The network N1 is, for example, a world-wide public communication network such as the Internet, and a wide area network (WAN) or other communication networks may be adopted. In addition, the network N1 may include a telephone communication network such as a mobile phone network and a wireless communication network such as Wi-Fi (registered trademark).

The vehicle 10 is, for example, a vehicle equipped with a battery 15 such as a BHV. The battery 15 supplies electric power to an electric motor that drives the vehicle 10. The vehicle 10 periodically transmits the state of the battery 15 to the server 30. For example, SOH may be calculated in the vehicle 10, and SOH may be transmitted to the server 30. It should be noted that not only SOH but also information of the status of deterioration of the battery 15 may be transmitted from the vehicle 10 to the server 30. For example, the vehicle 10 may transmit State Of Charge (SOC) or lithium-deposition amounts or the like to the server 30.

Note that, since the battery 15 has no communication function, when the battery 15 is removed from the vehicle 10, the vehicle 10 cannot thereafter transmit information on the state of deterioration of the battery 15 to the server 30. However, if the reuse business operator immediately starts using the battery 15 after the battery 15 is removed from the vehicle 10, it is considered that the deterioration state of the battery 15 at the time of the use start of the reuse business operator is substantially equal to the deterioration state of the battery 15 transmitted to the server 30 at the end of the time when the battery 15 is mounted on the vehicle 10. Therefore, it is assumed that the state of deterioration of the battery 15 when the reuse business operator starts using the battery 15 is equal to the state of deterioration of the battery 15 detected last in the vehicle 10. The battery 15 can be reused in units of cells, stacks, or packs, for example. In the vehicle 10, the state of deterioration may be detected for each unit such as a cell, a stack, or a pack, and transmitted to the server 30.

The business operator terminal 20 is a terminal used by a reuse business operator. The reuse business operator is a business operator that reuses the battery 15. The reuse business operator performs registration in advance with respect to the server 30 via the business operator terminal 20. The registered information includes information on the usage environment of the battery 15 and information on the performance of the battery 15 requested by the reuse business operator. The information on the usage environment of the battery 15 includes, for example, information on the amount of electric power input to the battery 15, and information on the type of renewable energy such as solar light, wind power, and geothermal heat. Note that the amount of electric power inputted to the battery 15 may be a power generation amount (kWh) when the battery 15 is used in a power plant. The information related to the usage environment is information related to the degree of deterioration of the battery 15.

Further, the information on the performance of the battery 15 requested by the reuse business operator includes, for example, information on the upper limit value and the lower limit value of SOC requested by the reuse business operator, information on the lower limit value of the capacity of the battery 15, or information on the output of the battery 15. The information on the required performance of the battery 15 is information related to the usage limit of the battery 15.

Then, the server 30 predict the time when the reuse business operator ends the use of the battery 15 based on SOH at the time when the reuse business operator starts the use of the battery 15 and the information registered by the reuse business operator. The time when the reuse business operator ends the use of the battery 15 is also a time when the battery 15 is collected as a recycled material. Here, FIG. 2 is a diagram illustrating the transition of SOH of the battery 15. A period indicated by “vehicle” in FIG. 2 is a period in which the battery 15 is mounted on the vehicle 10. In addition, the period indicated by “reuse business operator (prediction)” is a period in which the reuse business operator uses the battery 15, and is a period in which a predicted value based on information registered by the reuse business operator is indicated. In FIG. 2, the “request SOH” is a SOH requested by the reuse business operator and serves as an index for the reuse business operator to replace the battery 15. Further, in FIG. 2, the time point indicated by “recovery time prediction” is the time point at which the server 30 predicts the time point at which the battery 15 is recovered from the reuse business operator. The time point indicated by the “recovery time prediction” is also the time point at which the reuse business operator starts to use the battery 15. In FIG. 2, a time point indicated by “recovery” is a time point at which the battery 15 is recovered from the reuse business operator, which is predicted by the server 30. The time point indicated by “recovery” is also the time point at which SOH equals the required SOH.

In FIG. 2, the time point indicated by “recovery” is obtained by using a statistical method such as regression analysis or a machine learning model, for example. The trend in the decline in SOH during the period indicated by “Reuse business operators (forecasts)” is hardly affected by the trend in the decline in SOH during the period indicated by “vehicle.” Therefore, the server 30 can predict the transition of SOH according to SOH at the time when the reuse business operator starts using the battery 15 and the usage environment of the battery 15 by the reuse business operator. It should be noted that it is not necessarily required to predict the transition of SOH. For example, the recovery time of the battery 15 may be outputted by inputting SOH, the usage environment of the battery 15, and the required performance of the battery 15 to the learned machine learning model.

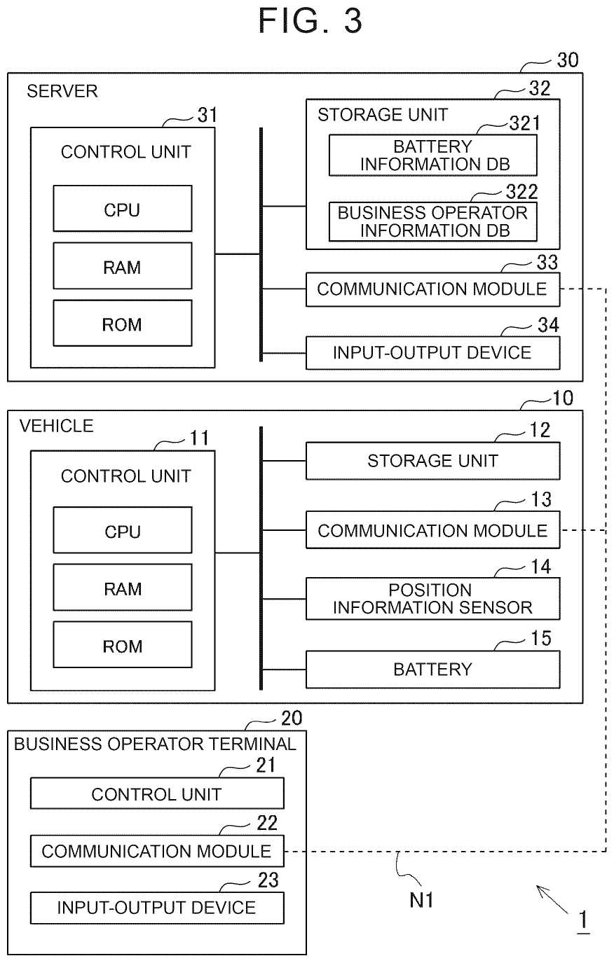

FIG. 3 is a block diagram schematically illustrating an example of the configuration of each of the vehicle 10, the business operator terminal 20, and the server 30 constituting the system 1 according to the present embodiment. The server 30 includes a control unit 31, a storage unit 32, a communication module 33, and an input/output device 34.

The server 30 can be configured as a computer including a processor (such as a CPU, GPU), a main storage device (such as a RAM, ROM), and a secondary storage device (such as a EPROM, a hard disk drive, and a removable medium). The secondary storage device stores an operating system (OS), various programs, various tables, and the like, and by executing the programs stored therein, it is possible to realize functions (software modules) that meet predetermined objectives, as will be described later. However, some or all of the modules may be realized as hardware modules by, for example, hardware circuitry such as an ASIC, FPGA.

The control unit 31 is an arithmetic unit that realizes various functions of the server 30 by executing a predetermined program. The control unit 31 can be realized by, for example, a hardware processor such as a CPU. In addition, the control unit 31 may be configured to include a RAM, Read Only Memory (ROM), a cache memory, and the like. Details of the control unit 31 will be described later.

The storage unit 32 is a unit that stores information, and is configured by a storage medium such as a RAM, a magnetic disk, or a flash memory. The storage unit 32 stores a program executed by the control unit 31, data used by the program, and the like. In addition, a data base (a battery information DB 321 and a business operator information DB 322) is constructed in the storage unit 32. In the database, information collected from each vehicle 10 and information collected from a reuse business operator are stored.

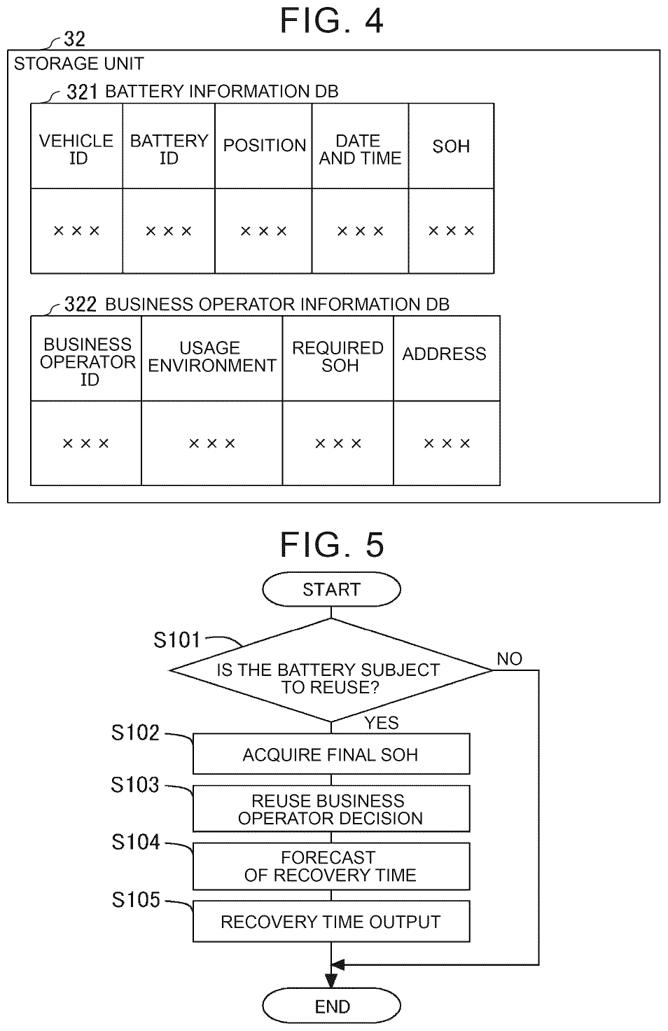

FIG. 4 is a diagram illustrating a table configuration of the battery information DB 321 and the business operator information DB 322. The battery information DB 321 stores the battery ID, the position information of the vehicle 10, the date and time information, and SOH information in association with the vehicle ID. The vehicle ID is identification information unique to the vehicle 10. The battery ID is an identity information unique to the battery 15. Note that the battery ID may be provided, for example, in units of reuse. The position information is information related to the position of the vehicle 10 when the information is transmitted from the vehicle 10, and is, for example, information indicated by coordinates. The date and time information is information on the date and time when SOH information is transmitted from the vehicle 10. SOH information is information related to SOH of the battery 15. The battery ID, the position information, the date and time information, and SOH information are transmitted from the vehicle 10 at predetermined timings in association with the vehicle ID. Hereinafter, the vehicle ID, the battery ID, the position information, the date and time information, and SOH information are collectively referred to as battery information. The control unit 31 stores the battery information received from the vehicle 10 in the battery information DB 321.

In addition, the business operator information DB 322 stores usage environmental information, required SOH information, and location information in association with the business operator ID. The business operator ID is information unique to the reuse business operator or the business operator terminal 20. The usage environment information is information related to the usage environment of the battery 15 by the reuse business operator. The required SOH is information related to SOH of the battery 15 required by the reuse business operator, and is information related to the performance of the battery 15 required by the reuse business operator. The location information is information related to the location of the business operator, and is information related to the location where the battery 15 is actually used. Hereinafter, the business operator ID, the usage environmental information, the required SOH information, and the location information are collectively referred to as business operator information. The control unit 31 stores the business operator information received from the business operator terminal 20 in the business operator information DB 322.

The communication module 33 is a communication interface for connecting the server 30 to the network N1. The communication module 33 may be configured to include, for example, a network interface board, a wireless communication interface for wireless communication, and the like. The server 30 can perform data communication with the vehicle 10 and the business operator terminal 20 via the communication module 33.

The input/output device 34 is a means for receiving an input operation performed by an operator and presenting information to the operator. Specifically, the input/output device 34 includes a device for inputting a mouse, a keyboard, or the like, and a device for outputting a display, a speaker, or the like. The input/output device 34 may be integrally formed of, for example, a touch panel display or the like.

Note that the specific hardware configuration of the server 30 can be omitted, replaced, or added as appropriate depending on the embodiment.

Next, the vehicle 10 will be described. The vehicle 10 includes a control unit 11, a storage unit 12, a communication module 13, a position information sensor 14, and a battery 15. The control unit 11 is an arithmetic unit that realizes various functions of the vehicle 10 by executing a predetermined program. The control unit 11 can be realized by, for example, a hardware processor such as a CPU. In addition, the control unit 11 may be configured to include a RAM, Read Only Memory (ROM), a cache memory, and the like.

The storage unit 12 is a unit that stores information, and is configured by a storage medium such as a RAM, a magnetic disk, or a flash memory. The storage unit 12 stores a program executed by the control unit 11, data used by the program, and the like. The storage unit 12 stores a default value of SOH.

The communication module 13 is a communication unit for connecting the vehicle 10 to the network N1. In the present embodiment, the vehicle 10 can communicate with other devices (for example, server 30) over a network N1 using a mobile communication service such as 3G, LTE, 5G, 6G.

The position information sensor 14 acquires position information (for example, latitude and longitude) of the vehicle 10 at a predetermined cycle. The position information sensor 14 is, for example, a Global Positioning System (GPS) receiver, a radio communication unit, or the like.

The control unit 11 of the vehicle 10 calculates SOH at predetermined intervals, for example. Then, the battery ID, the position information, the date and time information, and SOH information are transmitted to the server 30 in association with the vehicle ID. Note that the control unit 11 may acquire SOH by using known methods.

Next, the business operator terminal 20 will be described. The business operator terminal 20 includes a control unit 21, a communication module 22, and an input/output device 23. These components are the same as those of the control unit 31, the communication module 33, and the input/output device 34 of the server 30, and thus description thereof will be omitted.

Next, the control unit 31 of the server 30 will be described in detail. The control unit 31 of the server 30 predicts the time when the battery 15 is collected from the reuse business operator based on the battery information acquired from the vehicle 10 and the business operator information acquired from the business operator terminal 20. First, the control unit 31 acquires SOH corresponding to the corresponding battery 15. Since the battery 15 is associated with the vehicle ID and the battery ID, the control unit 31 accesses the battery information DB 321 based on the corresponding vehicle ID or the battery ID, and acquires the most recent SOH. That is, the control unit 31 extracts the last detected SOH when the battery 15 is mounted on the vehicle 10. This SOH is equal to SOH when the reuse business operator starts using the battery 15.

Next, the control unit 31 accesses the business operator information DB 322 and acquires information on each of the usage environment and the required SOH based on the business operator ID corresponding to the reuse business operator. Then, the recovery time is calculated on the basis of the most recent SOH, the usage environment, and the required SOH. This calculation can be obtained using a statistical method such as regression analysis or a learned machine learning model. The calculation formula or model for calculating the recovery time is stored in the storage unit 32. After calculating the recovery time, the control unit 31 outputs the recovery time from the input/output device 34 together with the location of the reuse business operator. The location of the reuse business operator is output as a place to recover the battery 15. Note that the control unit 31 can also transmit information regarding the recovery time of the battery 15 and the location of the reuse business operator to another server or terminal via the communication module 33.

Note that the control unit 31 may be used to acquire the time when the battery 15 is actually collected from the reuse business operator and to improve the accuracy of predicting the recovery time. For example, the time when the battery 15 is actually collected may be used as teacher data in machine learning.

FIG. 5 is a flowchart illustrating a process of outputting a recovery time of the battery 15 in the server 30. The flowchart illustrated in FIG. 5 is executed in the server 30 at predetermined time intervals. The battery information DB 321 and the business operator information DB 322 will be described on the assumption that the required information is already stored.

In S101, the control unit 31 determines whether or not the battery 15 has become a reuse target. For example, the business operator who has removed the battery 15 from the vehicle 10 notifies the server 30 of the vehicle ID or the battery ID via the terminal of the business operator. The control unit 31 that has received this notification determines that the battery 15 has become a reuse target. The location of the business operator who has removed the battery 15 from the vehicle 10 may also be acquired. If an affirmative determination is made in S101, the process proceeds to S102, and if a negative determination is made, the routine ends.

In S102, the control unit 31 acquires the final SOH of the battery 15. The final SOH is SOH corresponding to the most recent date and time among SOH stored in the battery information DB 321. That is, the control unit 31 extracts the most recent SOH from SOH corresponding to the battery ID in the battery information DB 321.

In S103, the control unit 31 determines a reuse service business operator that provides the battery 15. The control unit 31 refers to the business operator information corresponding to the respective reuse business operators stored in the business operator information DB 322, and determines an optimum reuse business operator for providing the battery 15. For example, the first condition is that the required SOH corresponding to the reuse business operator is lower than the final SOH acquired in S102 by a predetermined value or more. Further, for example, the second requirement is that the location of the reuse business operator is within a predetermined distance from the location of the business operator who removed the battery 15 or the location corresponding to the final SOH stored in the battery information DB 321. Further, for example, the third condition is that the usage environment of the reuse business operator conforms to the specifications of the battery 15. The specifications of the battery 15 are stored in the storage unit 32 in association with the battery ID. The control unit 31 extracts a reuse business operator that satisfies all of these criteria from the business operator information DB 322. In the case where there is a plurality of such reuse business operators, it is possible to decide from among them as an arbitrary reuse business operator.

In S104, the control unit 31 predicts a time to recover the battery 15 from the reuse business operator. The control unit 31 calculates a recovery time by using a calculation formula or a model stored in the storage unit 32. Thus, the control unit 31 predicts the recovery time. Then, in S105, the control unit 31 outputs the recovery time of the battery 15 to the input/output device 34. At this time, the battery ID and the location of the reuse business operator may be output together.

As described above, according to the present embodiment, when the control unit 31 determines a business operator to reuse the battery 15, it is possible to predict a time and a place at which the battery 15 is collected as a recycled material from the reuse business operator. That is, the control unit 31 can predict when and where the recycled material can be collected. In addition, the reuse business operator can obtain, for example, information on the battery 15 from the server 30. Further, the reuse business operator can obtain the battery 15 satisfying its own requirements.

### OTHER EMBODIMENTS

The above embodiments are only examples, and the disclosure may be carried out with various modifications without departing from the essence thereof. The processes and means described in the present disclosure can be freely combined and implemented as long as no technical contradiction occurs. Further, the processes described as being executed by one device may be shared and executed by a plurality of devices. Alternatively, the processes described as being executed by different devices may be executed by one device. In the computer system, it is possible to flexibly change the hardware configuration (server configuration) for realizing each function.

The disclosure can also be implemented by providing a computer program in which the functions described in the embodiments are implemented to a computer, and by one or more processors included in the computer reading and executing the program. Such a computer program may be provided to the computer by a non-transitory computer-readable storage medium connectable to the system bus of the computer, or may be provided to the computer via a network. The non-transitory computer-readable storage medium is, for example, a disc of any type such as a magnetic disc (floppy (registered trademark) disc, hard disk drive (HDD), etc.), an optical disc (compact disc read-only memory (CD-ROM), digital versatile disc (DVD), Blu-ray disc, etc.), a read only memory (ROM), a random access memory (RAM), an erasable programmable read only memory (EPROM), an electrically erasable programmable read only memory (EEPROM), a magnetic card, a flash memory, an optical card, and any type of medium suitable for storing electronic commands.

What is claimed is:

1. An information processing device comprising a control unit configured to execute
acquiring, with respect to a battery that is to be reused by a business operator, first information relating to deterioration of the battery when starting reuse of the battery,
acquiring second information regarding a usage environment of the battery by the business operator,
acquiring third information regarding performance of the battery that is required by the business operator, and
outputting a recovery time of the battery after the business operator uses the battery, in accordance with the first information, the second information, and the third information.

2. The information processing device according to claim 1, wherein the second information contains at least one of information regarding a type of renewable energy for charging the battery, and information regarding an amount of electric power input to the battery.

3. The information processing device according to claim 1, wherein the third information contains at least one of information regarding a lower limit value of a capacity of the battery, and information regarding an output of the battery.

4. The information processing device according to claim 1, wherein the control unit outputs, as a recovery time of the battery, a time at which the performance of the battery no longer satisfies the performance of the battery that is required by the business operator.

5. The information processing device according to claim 1, wherein the control unit acquires the first information from a vehicle equipped with the battery before reuse of the battery, and
acquires the second information and the third information from a terminal of the business operator.
